(19) United States
(12) Patent Application Publication
(10) Pub. No.: US 2007/0251818 A1
(43) Pub. Date: Nov. 1, 2007

(54) Copper physical vapor deposition targets and methods of making copper physical vapor deposition targets

(76) Inventors: Wuwen Yi, Veradale, WA (US); Susan D. Strothers, Spokane, WA (US)

Correspondence Address: WELLS ST. JOHN P.S., 601 W. FIRST AVENUE, SUITE 1300, SPOKANE, WA, 99201, US

(21) Appl. No.: 11/415,621

(22) Filed: May 1, 2006

(51) Int. Cl. C23C 14/00

(52) U.S. Cl. 204/298.12

(57) ABSTRACT

The invention includes physical vapor deposition targets formed of copper material and having an average grain size of less than 50 microns and an absence of course-grain areas throughout the target. The invention encompasses a physical vapor deposition target of a copper material and having an average grain size of less than 50 microns with a grain size standard deviation of less than 5% (1−σ) throughout the target. The copper material is selected from copper alloys and high-purity copper material containing greater than or equal to 99.9999% copper, by weight. The invention includes methods of forming copper physical vapor deposition targets. An as-cast copper material is subjected to a multistage processing. Each stage of the multistage processing includes a heating event, a hot-forging event, and a water quenching event. After the multistage processing the copper material is rolled to produce a target blank.

### TECHNICAL FIELD

The invention pertains to physical vapor deposition targets and methods of forming copper physical vapor deposition targets.

### BACKGROUND OF THE INVENTION

Physical vapor deposition (PVD) methods are used extensively for forming thin metal films over a variety of substrates, including but not limited to, semiconductive substrates during semiconductor fabrication. A diagrammatic view of a portion of an exemplary PVD apparatus 10 is shown in FIG. 1. Apparatus 10 includes a target assembly 12. The target assembly illustrated includes a backing plate 14 interfacing a PVD or “sputtering” target 16. Alternative assembly configurations (not shown) have an integral backing plate and target. Such targets can be referred to as ‘monolithic’ targets, where the term monolithic indicates being machined or fabricated from a single piece of material and without combination with an independently formed backing plate.

Typically, apparatus 10 will include a substrate holder 18 for supporting a substrate during a deposition event. A substrate 20, such as a semiconductive material wafer, is provided to be spaced from target 16. A surface 17 of target 16 can be referred to as a sputtering surface. In operation, sputtered material 24 is displaced from surface 17 of the target and deposits onto surfaces within the sputtering chamber including the substrate, resulting in formation of a thin film 22.

Sputtering utilizing system 10 is most commonly achieved with a vacuum chamber by, for example, DC magnetron sputtering or radio frequency (RF) sputtering.

Various materials including metals and alloys can be deposited using physical vapor deposition. Copper materials including high-purity copper and copper alloys are utilized extensively for forming a variety of thin film and structures during semiconductor fabrications. Sputtering targets are typically made of high-purity materials since the purity of materials can affect the deposited film with even minute particle-inclusions such as oxides or other non-metallic impurities can lead to defective or imperfect devices. For purposes of the present description the term ‘high-purity’ refers to the metallic purity in terms of the amount or percent by weight of a metal material (excluding gases) which consists of a particular metal or alloy. For example, a 99.9999% pure copper material refers to a metal material where 99.9999% of the total non-gas content by weight is copper atoms.

In addition to material purity, factors such as the grain size of a target material and the grain size uniformity of the material can also affect the quality of a resulting thin film produced utilizing the particular target. In general, a relatively small grain size is desirable for PVD targets to produce high quality thin films. However, it has recently been shown that conventional methodology for producing high-purity copper and copper alloy targets results in anomalous areas of coarse grains in the final target. It is desirable to develop targets having improved grain size uniformity and methodology for producing targets with improved grain size uniformity.

### SUMMARY OF THE INVENTION

In one aspect the invention encompasses physical vapor deposition targets. The targets are formed of copper material and have an average grain size of less than 50 microns. The targets additionally have an absence of course-grain areas throughout the target.

In one aspect the invention encompasses a physical vapor deposition target of a copper material and having an average grain size of less than 50 microns with a grain size non-uniformity (standard deviation) of less than 5% (1−σ) throughout the target. The copper material is selected from the group consisting of high-purity copper material containing greater than or equal to 99.999% copper, by weight, and copper alloys.

In one aspect the invention encompasses methods of forming copper physical vapor deposition targets. The methods include providing an as-cast copper material and performing a multistage processing of the as-cast material. Each stage of the multistage processing includes a heating event, a hot-forging event, and a water quenching event. After the multistage processing the copper material is rolled to produce a target blank.

### BRIEF DESCRIPTION OF THE DRAWINGS

Preferred embodiments of the invention are described below with reference to the following accompanying drawings.

The patent or application file contains at least one drawing executed in color. Copies of this patent or patent application publication with color drawing(s) will be provided by the Patent and Trademark Office upon request and payment of the necessary fee.

FIG. 1 is a diagrammatic view of a portion of an exemplary physical vapor deposition apparatus.

FIG. 2 is a flowchart diagram outlining methodology in accordance with one aspect of the invention.

FIG. 3 shows a comparison of grain structures of target blanks produced utilizing conventional methodology (Panel A) and methodology in accordance with the invention (Panel B).

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

In general the invention involves production of physical vapor deposition targets having improved grain size uniformity such that areas of course grains are significantly reduced or eliminated relative to targets produced utilizing conventional methodology. Specifically, the invention was developed for production of high-purity copper targets and high-purity copper alloy targets where the term “high-purity” typically refers to a base metallic purity of greater than or equal to 99.99%. Where the material is an alloy, the term “high purity” refers to the purity of the base copper to which one or more alloying elements have been added. Although described primarily with respect to copper and copper alloy targets it is to be understood that methodology of the invention can be adapted for production of targets of alternative metal or alloy materials.

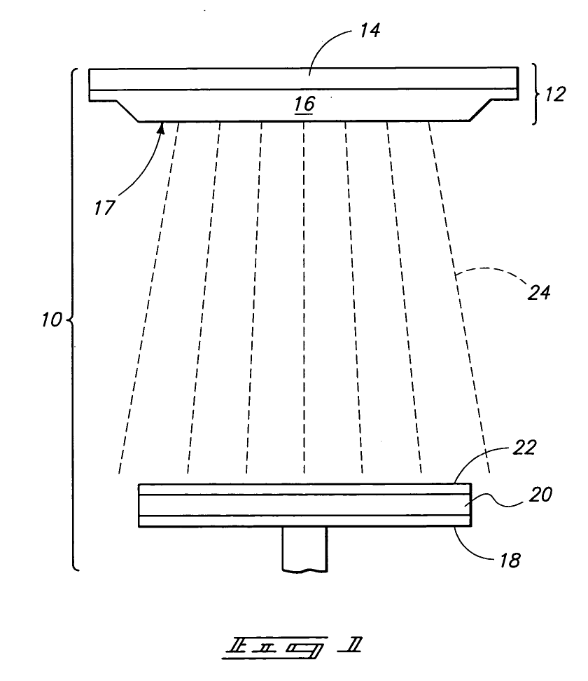

Targets in accordance with the invention can be produced to have a target size and shape configuration appropriate for utilization in conventional or yet to be developed PVD deposition systems. Targets of the invention can be constructed for utilization with a backing plate in configurations such as that illustrated in FIG. 1. Alternatively, targets of the invention can be monolithic targets which can be utilized in an absence of an independently formed backing plate.

Copper targets in accordance with the invention can comprise high-purity copper or high-purity copper alloy, can consist essentially of high-purity copper or high-purity copper alloy, or can consist of high-purity copper or high-purity copper alloy. Where the copper material comprises a copper alloy, a material can preferably comprise copper and at least one element selected from the group consisting of Ag, Al, In, Mg, Sn, and Ti. Preferred copper alloys can contain less than or equal to about 10% of total alloying elements, by weight.

Sputtering of high-purity copper and copper alloy targets formed by conventional methodology has revealed the presence of course grain regions with such regions having large grains of about 100-200 microns or greater. The presence of such grains has been determined to affect the quality and uniformity of thin films produced utilizing such targets. In contrast, copper targets and copper alloy targets in accordance with the invention have reduced numbers and areas of course grains regions, and in particular instances methodology in accordance with the invention entirely eliminates course grains throughout the target.

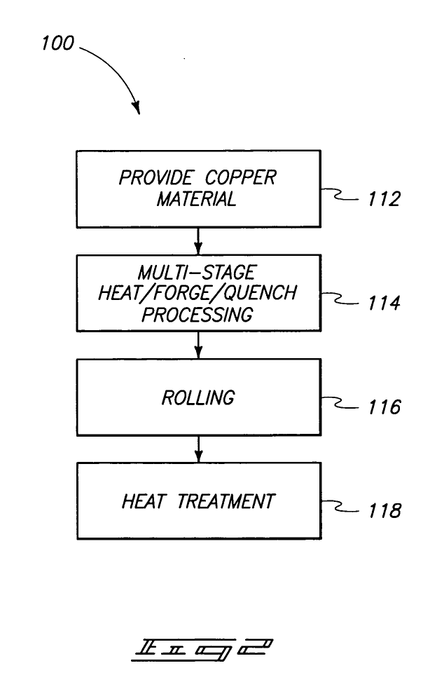

Methodology in accordance with the invention is described generally with reference to FIG. 2. A general process 100 includes providing a copper material in an initial step 112. Typically, the copper material will be an as-cast billet either of a high-purity copper or of copper alloy. The copper material is subsequently subjected to a thermomechanical processing 114. In contrast to conventional methodology, thermomechanical processing in accordance with the invention can utilize multi-stage processing where each stage includes a heating event, followed by a forging event and subsequent quenching. The multi-stage processing will include at least two stages or “rounds” of heating, forging and quenching and can comprise three or greater than three stages.

During the multi-stage processing the temperature during the heating event is not limited to a particular value and can vary depending upon the specific material being processed. Further, an initial stage of the multi-stage processing can utilize a heating event that is conducted at a first temperature while a second stage heating event is conducted at a second temperature which varies relative to the first temperature. Typically, each heating event in the multi-stage processing is conducted at a temperature of greater than about 900° F. In particular instances, high-purity copper and particular copper alloys will be heated at 1050° F. for at least 30 minutes during each heating event, and in some instances may be heated for at least 60 minutes. It is to be understood that the heating time will vary depending upon the particular heating temperature.

During the multi-stage processing, forging events can utilize hot upset forging. Typically a forging event conducted in a first stage of multi-stage processing will produce a forged block having a first height (block thickness) and a subsequent forging event conducted in a subsequent stage of the multi-stage processing will produce a forged block having a second reduced height. After each forging event the forged block is preferably quenched into cold water. Such quenching is preferably conducted for at least 8 minutes with specific time being determined by the material mass and block thickness.

Multi-stage processing ultimately results in a final forged block which is subsequently subjected to a rolling process 116. Rolling process 116 preferably comprises cold rolling for further thickness reduction of the forged block. Rolling process 116 produces a rolled blank which is typically machined and cleaned to form a target blank.

The rolled blank can be subjected to additional processing comprising a heat treatment 118. Where the target is to be bonded to a backing plate, such as a CuCr backing plate, the heat treatment can be performed as part of the target/backing plate bonding process. Typically, such bonding is conducted utilizing hot isostatic pressing (HIPping). The HIPping will typically be conducted at a temperature of at least about 480°. It is to be understood however, that the particular bonding temperature during HIPping can vary depending upon the particular high-purity copper material or copper alloy material being bonded. In specific instances where a high-purity copper material or particular copper alloys are utilized, the bonding will be performed utilizing a temperature of approximately 662° F. for about 2 hours. In accordance with the invention, such bonding produces a diffusion bond having a bond strength of greater than about 20 ksi.

After bonding, the target/backing plate assembly can be further processed by machining to form a finished copper or copper alloy target assembly. The heat treatment performed as part of the bonding process results in annealing or recrystallization of the copper material. The combination of the multi-stage processing and recrystallization results in fine grain size and uniform grain distribution with essentially no course grain areas, and in particular instances results in an absence of course grain areas throughout an entirety of the target.

In an alternative embodiment where the rolled blank is to be utilized as a target in an absence of a backing plate, the rolled blank can be subjected to heat treatment 118 by annealing/recrystallizing at a heat treatment temperature as discussed above with respect to heat treatment process 118. In general, the heat treatment will comprise annealing/recrystallizing at a temperature of at least about 480° F., and in particular instances about 662° F. for about 2 hours. After annealing, the target blank is machined to produce a monolithic copper or copper alloy target for use without a backing plate. The heat treatment results in recrystallization. Due to the previous multi-stage processing, the recrystallization results in essentially no course grains and typically an entire elimination of course grains throughout the monolithic target.

Whether the target material is high-purity copper or copper alloy, and whether a monolithic target or target assembly is formed, targets produced utilizing methodology as presented in FIG. 2, consistently have average grain sizes of less than 50 microns with a standard deviation of less than 10% (1−σ). In particular instances the standard deviation is less than 5% (1−σ).

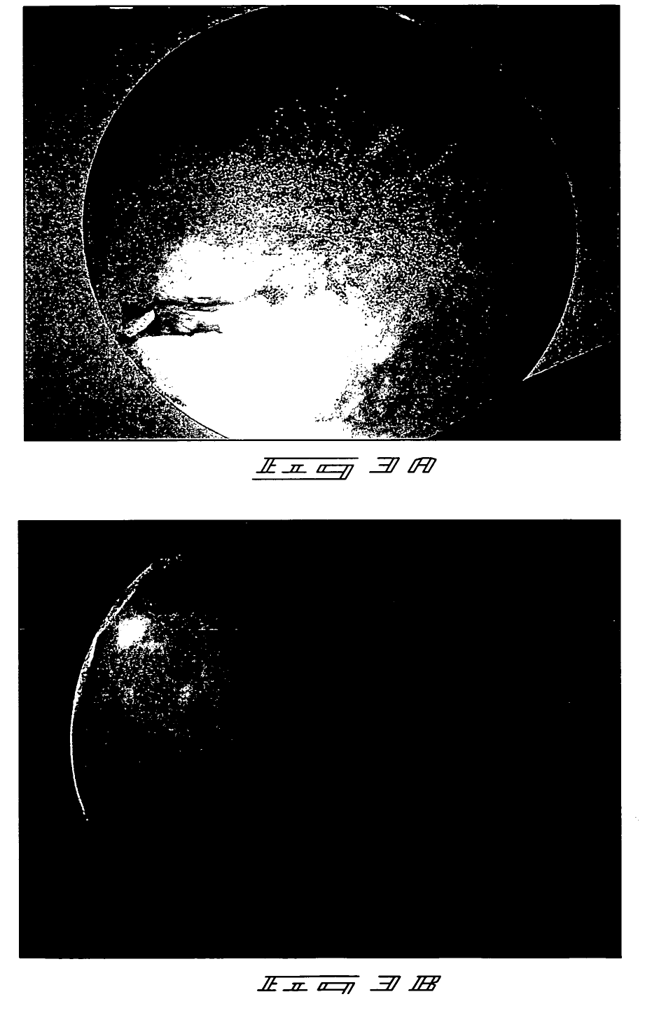

Referring to FIG. 3, a comparison of target blanks produced by conventional methodology (Panel A) and methodology in accordance with the invention (Panel B) is shown. The conventional target blank shown in Panel A has visible rough/shiny regions corresponding to course grain areas having grains of sizes exceeding 100-200 microns. In contrast, the target blank shown in Panel B produced in accordance with methodology of the invention has a notable absence of any such rough/shiny regions and in fact has an absence of course grain regions.

Processing of particular materials in accordance with the invention is further described in the examples below. It is to be understood that the examples are not intended to limit the invention to any particular material compositions, processing temperatures or conditions and are set forth to illustrate the effectiveness of the inventive processing.

### EXAMPLE 1

A 6 inch diameter by 10 inch high as-cast copper alloy billet was heated at 1050° F. for 60 minutes. The billet was then subjected to hot forging to a first block height of 6.0 inches. The block was quenched into cold water for longer than 8 minutes. The quenched block was reheated at 1050° F. for 30 minutes followed by hot forging to a resulting second height of 3.3 inches. The twice forged block was quenched into water for greater than 8 minutes. The resulting forged block was then cold rolled to an ultimate thickness of 0.93 inches. The rolled blank was machined and cleaned and was subsequently bonded to a CuCr backing plate by hot isostatic pressing at 662° F. for 2 hours. The resulting target/backing plate assembly was machined to a finished copper alloy target assembly. The final target had a uniform grain size distribution with a standard deviation of less than 5% (1−σ) and an average grain size of less than 50 microns.

### EXAMPLE 2

A rolled copper alloy blank was prepared as described above in Example 1. The rolled alloy blank was annealed by heat treating at 662° F. for 2 hours. The resulting target blank was machined to produce a monolithic copper alloy target which had a resulting grain size average less than 50 microns and a uniform grain size distribution having a standard deviation of less than 5% (1−σ) throughout the target.

### EXAMPLE 3

A high-purity (99.9999% by weight) copper as-cast billet was subjected to two rounds of heating, hot forging, and water quenching, followed by cold rolling as described in Example 1. The rolled copper blank was machined and cleaned and was bonded to a CuCr backing plate at 662° F. for 2 hours utilizing hot isostatic pressing. After bonding, the assembly was machined to form a finished copper target assembly. The resulting bond strength was greater than 20 ksi. The target had an average grain size of less than 50 microns and a grain size distribution standard deviation of less than 5% (1−σ).

### EXAMPLE 4

A rolled high-purity copper blank was produced as described in Example 3. The blank was subjected to annealing by heating at 662° F. for 2 hours. The target blank was subsequently machined to produce a monolithic target. The monolithic target had an average grain size of less than 50 microns and a grain size distribution uniformity of less than 5% (1−σ).

For each of the four targets produced above in the examples the target had an absence of course grain regions throughout the entirety of the target. The results of studies of grain sizes for targets of the invention as compared to conventional targets is presented in Table I. Resulting grain sizes for a copper-aluminum alloy target produced in accordance with the invention is presented in Rows 3 and 4 of the table, as compared to a target of identical composition prepared utilizing conventional processing (Rows 1 and 2).

TABLE I
Grain size (microns) comparison at indicted target locations for
conventional targets and targets of the invention.

| | Edge | Middle radius | Center | Average |
|---|---|---|---|---|
| | μm | μm | μm | μm |
| Top of conventional | 27 | 80 | 64 | 57 |
| target | | | | |
| Bottom of | 32 | 29 | 43 | 35 |
| conventional target | | | | |
| Top of target of the | 32 | 29 | 32 | 31 |
| invention | | | | |
| Bottom of target of the | 32 | 29 | 32 | 31 |
| invention | | | | |

Additional grain size determinations were performed for multi-stage processed targets of the invention. The results for four independently formed copper-aluminum alloy targets are presented in Table 2. Grain size determinations were performed at multiple target levels (surface, 0.3 inch thickness and 0.6 inch thickness), with 9 samples being studied per level. The standard deviation per level and for each target overall are specified.

TABLE 2
Grain size (microns) uniformity for multi-stage processed targets.

| | | | | | | | | | | | | Plane | Overall |
|---|---|---|---|---|---|---|---|---|---|---|---|---|---|
| | | | | | | | | | | | | std | std |
| | | | | | | | | | | | | dev | dev |
| Target | | 1 | 2 | 3 | 4 | 5 | 6 | 7 | 8 | 9 | Ave | (1σ) | (1σ) |
| 1 | 0.0″ | 29 | 29 | 32 | 29 | 32 | 32 | 35 | 32 | 29 | 31 | 2.1 | 4.1 |
| | 0.3″ | 29 | 32 | 32 | 35 | 29 | 29 | 29 | 29 | 32 | 31 | 2.2 | |
| | 0.6″ | 29 | 29 | 32 | 29 | 37 | 48 | 32 | 35 | 37 | 34 | 6.1 | |
| 2 | 0.0″ | 32 | 32 | 32 | 32 | 48 | 37 | 32 | 32 | 35 | 35 | 5.3 | 4.0 |
| | 0.3″ | 32 | 27 | 32 | 32 | 32 | 29 | 29 | 29 | 32 | 30 | 1.9 | |
| | 0.6″ | 29 | 29 | 32 | 32 | 27 | 29 | 29 | 35 | 35 | 31 | 2.9 | |
| 3 | 0.0″ | 35 | 29 | 35 | 35 | 32 | 32 | 32 | 48 | 32 | 34 | 5.5 | 4.5 |
| | 0.3″ | 27 | 32 | 29 | 32 | 29 | 29 | 29 | 32 | 29 | 30 | 1.8 | |
| | 0.6″ | 32 | 29 | 29 | 32 | 29 | 35 | 43 | 35 | 32 | 33 | 4.5 | |
| 4 | 0.0″ | 32 | 32 | 48 | 29 | 32 | 35 | 37 | 35 | 37 | 35 | 5.5 | 4.4 |
| | 0.3″ | 29 | 27 | 29 | 29 | 29 | 29 | 32 | 29 | 32 | 29 | 1.6 | |
| | 0.6″ | 29 | 27 | 32 | 29 | 37 | 37 | 32 | 32 | 32 | 32 | 3.4 | |

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

The invention claimed is:

1. A physical vapor deposition target comprising:
a copper material;
an average grain size of less than 50 microns; and
an absence of coarse-grain areas throughout the target.

2. The target of claim 1 wherein the grain size standard deviation throughout an entirety of the target is less than 10% (1−σ).

3. The target of claim 1 wherein the grain size standard deviation throughout an entirety of the target is less than 5% (1−σ).

4. The target of claim 1 wherein the target is a diffusion bonded target and wherein the diffusion bond has a bond strength of greater than or equal to 20 ksi.

5. The target of claim 1 wherein the target is monolithic.

6. The target of claim 1 wherein the copper material is high-purity copper having a purity of greater than or equal to 99.9999% copper, by weight.

7. The target of claim 1 wherein the copper material is a copper alloy.

8. The target of claim 7 wherein the copper alloy comprises copper and one or more elements selected from the group consisting of Ag, Al, In, Mg, Sn, and Ti.

9. A physical vapor deposition target comprising a copper material, having an average grain size of less than 50 microns and having a grain size standard deviation of less than 5% (1−σ) throughout the target, the copper material being selected from the group consisting of copper alloys and high-purity copper material containing greater than or equal to 99.999% copper by weight.

10. A method of forming a copper physical vapor deposition target comprising:
providing an as-cast copper material;
performing a multi-stage processing of the as-cast material, each stage comprising a heating event, a hot forging event and a water-quenching event; and
after the multi-stage processing, rolling the copper material to produce a target blank.

11. The method of claim 10 further comprising annealing the target blank.

12. The method of claim 11 wherein the annealing is conducted at a temperature of at least about 480° F.

13. The method of claim 10 further comprising hot isostatic pressing the blank to a backing plate to produce a diffusion bond having a bond strength of greater than or equal to 20 ksi.

14. The method of claim 13 wherein the isostatic pressing is conducted at a temperature of about 662° F. for about 2 hours.

15. The method of claim 10 further comprising machining the target blank to produce a monolithic target.

16. The method of claim 10 wherein the copper material is high-purity copper having a purity of greater than or equal to 99.9999% copper, by weight.

17. The method of claim 10 wherein the copper material is a copper alloy.

18. The Method of claim 17 wherein the copper alloy comprises copper and one or more elements selected from the group consisting of Ag, Al, In, Mg, Sn, and Ti.

19. The method of claim 10 wherein the multi-stage process comprises a first stage comprising a first heating event wherein the copper material is heated at a temperature of greater than or equal to 900° F., and a second stage comprising a second heating event wherein the copper material is heated at a temperature of greater than or equal to 900° F. for at least 30 minutes.
